(19) United States
(12) Patent Application Publication
(10) Pub. No.: US 2005/0041510 A1
(43) Pub. Date: Feb. 24, 2005

(54) Method and apparatus for providing interprocessor communications using shared memory

(76) Inventors: Jean Khawand, Miami, FL (US); David J. Hayes, Lake Worth, FL (US); Charbel Khawand, Miami, FL (US); Bin Liu, Weston, FL (US); Jianping W. Miller, Coral Springs, FL (US)

Correspondence Address: MOTOROLA, INC., 1303 EAST ALGONQUIN ROAD, IL01/3RD, SCHAUMBURG, IL, 60196, US

(21) Appl. No.: 10/643,327

(22) Filed: Aug. 19, 2003

(51) Int. Cl. G11C 8/00

(52) U.S. Cl. 365/230.03

(57) ABSTRACT

A method for transferring messages between a first processor (102) and a second processor (104) includes the step of requesting an empty message buffer (106) from the first processor or master processor (102). The first processor (102) sends an empty message buffer pointer (108) which the second processor uses to locate the allocated memory within the shared memory (112). The second processor (104) then loads its message in the allocated memory area and sends the message (110). After receiving the message, the first processor (102) releases the allocated memory area found in shared memory (112) so that it can be used in the future. An electronic device such as a radio communication device that uses the shared memory scheme is also described.

### TECHNICAL FIELD

This invention relates in general to the field of electronics and more specifically to a method and apparatus for providing interprocessor communications (IPC) using shared memory.

### BACKGROUND

Prior art techniques for sharing memory used for exchanging messages between two or more processors in an electronic system typically require that the two or more processors be responsible for their own “transmit memory” (memory used by a processor to load data that will be transmitted to another processor). Each processor is responsible for allocating and freeing message memory used for storing messages sent to the other processor(s). These prior art techniques force the static division of shared IPC memory between the two or more processors, meaning that a predetermined amount of the shared memory will need to be allocated to each processor. This may create a suboptimal use of the total shared memory that is available if the transmission of messages between the processors is asymmetrical (e.g., one processor sends more messages than another processor). With pre-allocated memory schemes, one processor's shared memory allocation may be under utilized while a second processor's shared memory allocation may not be enough for its message transmission needs. Given the above, a need exists in the art for a method and apparatus which can help improve the sharing of memory between two or more processors.

### BRIEF DESCRIPTION OF THE DRAWINGS

The features of the present invention, which are believed to be novel, are set forth with particularity in the appended claims. The invention may best be understood by reference to the following description, taken in conjunction with the accompanying drawings, in the several figures of which like reference numerals identify like elements, and in which:

FIG. 1 shows a diagram highlighting a method of multiprocessor sharing of memory in accordance with an embodiment of the invention.

FIG. 2 shows a block diagram of a radio communication device in accordance with an embodiment of the invention.

FIG. 3 shows a flow chart highlighting the steps taken by a first (“master”) processor to transfer a message to a second processor in accordance with an embodiment of the invention.

FIG. 4 shows a flow chart highlighting the steps taken by a second (“non-master”) processor to send a message to a first processor in accordance with an embodiment of the invention.

### DETAILED DESCRIPTION OF THE PREFERRED EMBODIMENT

While the specification concludes with claims defining the features of the invention that are regarded as novel, it is believed that the invention will be better understood from a consideration of the following description in conjunction with the drawing figures.

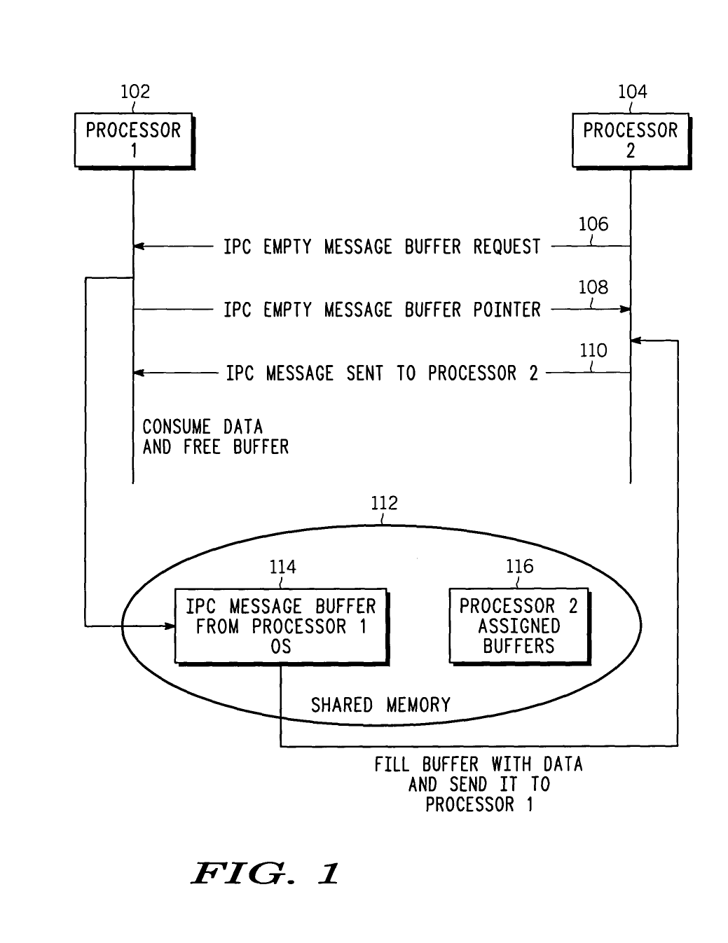

In order to overcome the problems previously mentioned with some prior art IPC communications, the “transmit” memories of two or more processors are combined into one memory space managed by one of the processors in the system. In FIG. 1, there is shown a diagram illustrating the transfer of messages between a first (“master”) processor (processor 1)102 and a second processor (processor 2) 104. The first processor 102 allocates memory among the processor 102 and 104, as the need for memory arises. The processors 102 and 104 can comprise any type of processor such as a microprocessor, microcontroller, or digital signal processor (DSP).

When the second processor 104 needs to send a message to the first processor 102, it sends an IPC empty message buffer request message as shown in step 106 to the first processor 102. The first processor 102 responds by sending an IPC empty message buffer pointer to the second processor 104 (step 108). The empty message buffer pointer provides memory address information needed by the second processor 104 when accessing shared memory 112. The pointer informs the second processor 104 where in shared memory 112 it needs to start loading its message. Shared memory 112 can comprise Random Access Memory (RAM) or any other type of readable/writable memory known in the art.

The second processor 104 fills up the assigned message buffer 114 found in shared memory 112 and passes the message pointer back to the first processor 102 in step 110 so that it can read (consume) the data and free the previously assigned message buffer 114. Step 110 can include, in one embodiment, simply sending the message buffer pointer back to the first processor 102. In an alternate embodiment, the second processor 104 can send another type of message to the first processor 102 which lets it know which message buffer (in this example IPC message buffer 114) was assigned to the second processor 104.

In order to reduce the latency of the second processor 104 asking for a message buffer from the first processor 102, in an alternate embodiment of the invention, a small set of buffers 116 is made available all the time to the second processor 104. Buffers 116 are ready to be used without the need for the second processor 104 requesting the buffers 116 from the first processor 102. Once a buffer from the assigned buffers 116 is removed for use by the second processor 104, the second processor 104 sends a message to the first processor 102 which automatically replaces the buffer when it receives the message.

Referring to FIG. 2, there is shown an electronic device such as a radio communication device 200 in accordance with the invention. A first processor (processor #1) 202 is coupled to a second processor (processor #2) 204 and both processors are coupled to shared memory 206. A conventional transmitter and receiver section 208 provides for radio frequency transmissions of messages. User controls (e.g., keypad) 210 and display 212 provide an interface to the user of the radio communication device 200.

In another embodiment of the invention, a mailbox buffer such as a one word mailbox 218 can be used to store the memory buffer pointer in the second processor 204 that is sent by the first processor 202. A similar mailbox, mailbox 216, can be found in the first processor 202.

The mailboxes 216 and 218 are used to exchange pointers and short commands between the first 202 and second processors 204. Alternatively, an interrupt line 214 can be used by the first processor 202 to send an interrupt to the second processor 204. In response to receiving the interrupt, the second processor 204 reads a predetermined location in shared memory and locates the address pointer for the message buffer found in shared memory 206

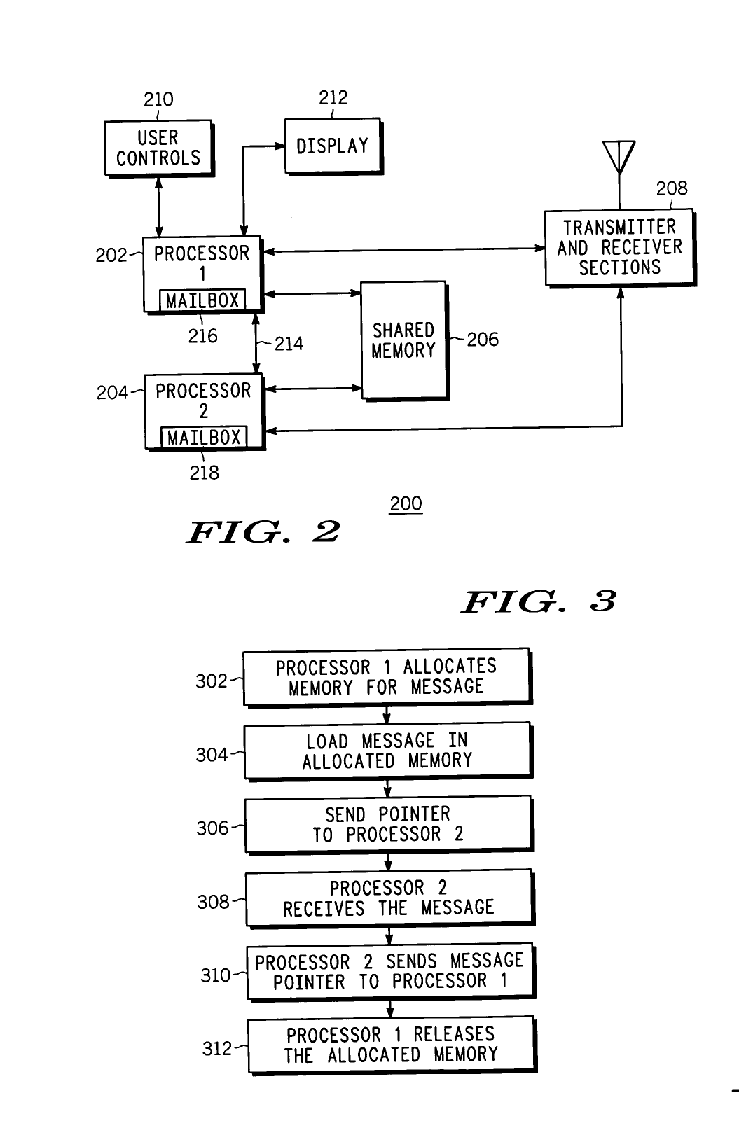

In FIG. 3, there is shown a flowchart highlighting the steps taken by the first processor 202 when sending a message to the second processor 204. In this example, the first processor 202 is the master processor in charge of memory allocation for the shared memory 206. In step 302, the first processor (processor 1) 202 allocates memory from shared memory 206 for a message it needs to transfer (transmit) to the second processor 204. In step 304, the first processor 202 loads the message in the allocated memory area. In step 306, the first processor 202 sends the pointer to the second processor 204. In step 308, the second processor 204 receives the message from the shared memory 206. In step 310, after the message is consumed by the second processor 204, the second processor 204 sends a message pointer to the first processor 202 (using a mailbox 216 or interrupt line 214) indicating that the message space can be released. Finally in step 312, the first processor 202 releases the allocated memory to the shared memory 206. The release of the allocated memory can be performed by the second processor 204, for example, by sending a message to the first processor 202 that it has received the message.

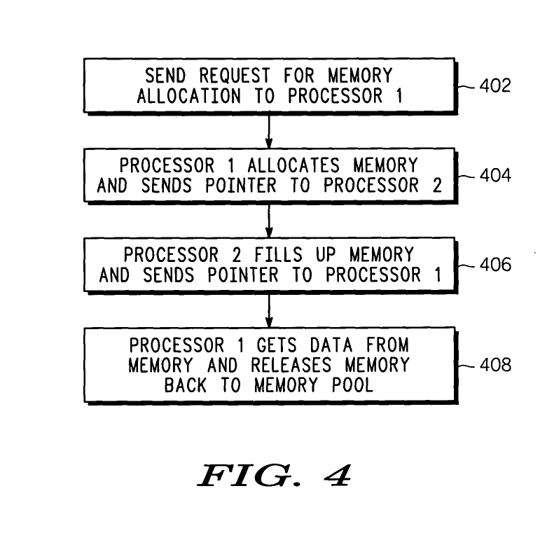

In FIG. 4, there is shown a flowchart highlighting the steps taken by the second processor 204 when requesting memory space for the transmission of a message to the first processor 202. In step 402, the second processor 204 sends a request for memory allocation to the first processor 202. In step 404, the first processor 202 allocates the required memory and sends a pointer to the second processor 204. In step 406, the second processor 204 loads the message in the allocated memory area and sends back the pointer to the first processor 202. Finally, in step 408, the first processor 202 retrieves the message from the allocated memory area and after retrieving the message, releases the allocated memory back to the memory pool.

The present invention allows for the implementation of a shared memory scheme that optimizes memory usage and minimizes overhead during message transfers between processors. By doing away with the static allocation of memory common in the prior art, the shared memory scheme of the present invention provides for an efficient memory allocation technique and system.

While the preferred embodiments of the invention have been illustrated and described, it will be clear that the invention is not so limited. Numerous modifications, changes, variations, substitutions and equivalents will occur to those skilled in the art without departing from the spirit and scope of the present invention as defined by the appended claims.

1. An electronic device, comprising:
a first processor;
a second processor coupled to the first processor;
shared memory coupled to the first and second processors; and
wherein the first processor manages the shared memory and allocates a message buffer to the second processor whenever the second processor needs to send a message to the first processor, and wherein the first processor sends a message buffer pointer to the second processor that directs the second processor to the message buffer.

2. An electronic device as defined in claim 1, wherein the first processor sends the message buffer pointer to the second processor in response to receiving an empty buffer request from the second processor.

3. An electronic device as defined in claim 2, wherein after receiving the message buffer pointer the second processor fills the message buffer with the message.

4. An electronic device as defined in claim 3, wherein after filling up the message buffer with the message, the second processor passes the message buffer pointer to the first processor.

5. An electronic device as defined in claim 4, wherein the first processor reads the message from the message buffer after receiving the message buffer pointer.

6. An electronic device as defined in claim 5, wherein after reading the message, the first processor releases the message buffer.

7. An electronic device as defined in claim 1, wherein a plurality of buffers assigned to the second processor are located in the shared memory.

8. An electronic device as defined in claim 7, wherein the plurality of buffers assigned to the second processor are used by the second processor without having to request them from the first processor.

9. An electronic device as defined in claim 8, wherein when the second processor needs to send a message to the first processor it loads a starting address of the message in one of the plurality of buffers assigned to the second processor.

10. An electronic device as defined in claim 1, wherein the electronic device comprises a radio communication device.

11. A method for providing interprocessor communication between first and second processors using a shared memory, the first processor assigned to manage the shared memory, the method comprising the steps of:
(a) sending a request from the second processor requesting an empty message buffer from the shared memory when the second processor needs to send a message to the first processor;
(b) sending a message buffer pointer from the first processor to the second processor in response to the request sent in step (a);
(c) using the message buffer pointer by the second processor to locate the empty message buffer in the shared memory where the message is going to be loaded; and
(d) loading the empty message buffer with the message.

12. A method as defined in 11, further comprising the step of:
(e) sending the message buffer pointer back to the first processor.

13. A method as defined in claim 12, wherein in response to step (e) the first processor performs the step of:
(f) reading the message.

14. A method as defined in claim 13, further comprising the step of:
(g) releasing the empty message buffer once step (f) has been performed.

15. A method for providing interprocessor communication between first and second processors using a shared memory, the first processor assigned to manage the shared memory, the method comprising the steps of:
at the first processor:
(a) allocating a memory buffer from the shared memory for use in loading a message to be sent to the second processor;
(b) loading the message in the memory buffer;
(c) sending a message buffer pointer to the second processor; and
at the second processor:
(d) using the message buffer pointer to locate the message in the shared memory.

16. A method as defined in claim 15, further comprising the step of:
at the second processor:
(e) reading the message; and
(f) sending the message buffer pointer back to the first processor.

17. A method as defined in claim 16, wherein the first processor upon receiving the message buffer pointer sent in step (f), releases the allocated memory buffer so it can be used for a future message.

18. A method as defined in 15, wherein step (c) is performed by the first processor sending the starting address of the allocated memory buffer to a memory located in the second processor.

19. A method as defined in claim 18, wherein the first processor sends an interrupt to the second processor once it has loaded the starting address of the allocated memory buffer in the memory located in the second processor.
